(19) United States
(12) Patent Application Publication
(10) Pub. No.: US 2026/0143999 A1
(43) Pub. Date: May 21, 2026

(54) SUPPORT APPARATUS

(71) Applicant: GUDENG PRECISION INDUSTRIAL CO., LTD., New Taipei City (TW)

(72) Inventors: MING-CHIEN CHIU, New Taipei City (TW); CHIA-HO CHUANG, New Taipei City (TW); CHENG-WU CHUNG, New Taipei City (TW); JING-JIE SOU, New Taipei City (TW); YU-HSIEN LEE, New Taipei City (TW); TZU-HSIANG WEI, New Taipei City (TW)

(73) Assignee: GUDENG PRECISION INDUSTRIAL CO., LTD., New Taipei City (TW)

(21) Appl. No.: 19/389,064

(22) Filed: Nov. 14, 2025

Related U.S. Application Data
(60) Provisional application No. 63/722,082, filed on Nov. 19, 2024.

(51) Int. Cl. H01L 21/673

(52) U.S. Cl. CPC H10P 72/1921; H10P 72/1911

(57) ABSTRACT

A support apparatus is provided, disposed in a semiconductor container. The support apparatus includes a body, including an upper surface and a lower surface that are opposite; and a bearing body, disposed on the upper surface of the body. The bearing body includes a shared bearing portion, a first bearing portion, and a second bearing portion. The bearing body is configured to dispose, based on a design pattern of a semiconductor substrate, the semiconductor substrate on the shared bearing portion and the first bearing portion, or the shared bearing portion and the second bearing portion.

This non-provisional application claims priority under 35 U.S.C. § 119(e) on U.S. provisional Patent Application No(s). 63/722,082 filed on Nov. 19, 2024, the entire contents of which are hereby incorporated by reference.

### BACKGROUND OF THE INVENTION

### 1. Field of the Invention

The present disclosure relates to an assembly of a semiconductor container, and in particular, to a support apparatus that can be assembled in the semiconductor container and is configured to carry a semiconductor substrate.

### 2. Description of the Related Art

During production and transportation of a semiconductor, a semiconductor container is usually used to store and place a semiconductor substrate such as a wafer, a photomask, a PCB, or a glass substrate. With development of semiconductor processing, requirements on production efficiency, a yield rate, and costs are increasingly high. How to improve the structure of the semiconductor container, improve operational efficiency, and/or reduce vibration of the semiconductor substrate during transportation, to improve the yield rate of processing and reduce the overall costs, has become an increasingly important topic.

A known semiconductor container usually includes a container body, a cover body, and a support apparatus. The container body has space that can accommodate a semiconductor substrate. The cover body is disposed at an outward opening of the space of the container body, and can cover the opening in an openable manner, to close the space accommodating the semiconductor substrate. The support apparatus is disposed inside the space of the container body, and configured to support the semiconductor substrate.

For a semiconductor container in a top opening form, for example, a top opening carrier, a support apparatus thereof is usually referred to as a tray. Each tray may be configured to bear a semiconductor substrate, and is placed inside a container body through an opening at the top of the container body.

### BRIEF SUMMARY OF THE INVENTION

However, an existing tray can only bear and limit a semiconductor substrate with a single size. When semiconductor substrates with different sizes need to be processed, trays of the corresponding sizes need to be respectively designed and produced. As a result, not only overall production costs are increased, but also space burdens in storage and management are caused.

In view of defects of the foregoing known technologies, the inventor feels that the prior art was inadequate, and therefore performs researching for overcoming. A support apparatus has been developed successfully, so that semiconductor substrates with different sizes can be universally borne.

The terms “one” or “a” as used herein for elements and components described in the present disclosure is only for convenient use and provides a common definition of the scope of the present disclosure, and should be interpreted as including one or at least one in the present disclosure. In addition, unless clearly indicating another meaning, a concept of being single also includes a condition of being plural.

Similar terms such as “bind”, “combine”, or “assemble” in the present disclosure mainly include forms such as being capable of being separated without breaking components after connection, enabling components to be incapable of being separated after connection, or the like, and can be selected by a person of ordinary skill in the art based on material or assembly requirements of the to-be-connected components.

To achieve the foregoing objective and other objectives, the present disclosure provides a support apparatus, disposed in a semiconductor container. The support apparatus includes: a body, including an upper surface and a lower surface that are opposite; and a bearing body, disposed on the upper surface of the body. The bearing body includes a shared bearing portion, a first bearing portion, and a second bearing portion. The bearing body is configured to dispose, based on a design pattern of a semiconductor substrate, the semiconductor substrate on the shared bearing portion and the first bearing portion, or the shared bearing portion and the second bearing portion.

In the foregoing support apparatus, the first bearing portion and the second bearing portion may be located on adjacent sides, and are configured to bear a design pattern of an appearance, a size, a thickness, or any combination thereof of a different semiconductor substrate.

In the foregoing support apparatus, upper surfaces of the first bearing portion and the second bearing portion are lower than the upper surface of the body, to define a recess at which the semiconductor substrate is borne.

In the foregoing support apparatus, the bearing body may include at least one bearing rib. The bearing rib is connected to the shared bearing portion and the first bearing portion, to the shared bearing portion and the second bearing portion, to the shared bearing portion, the first bearing portion, and the second bearing portion, or a combination thereof.

In the foregoing support apparatus, a plurality of elastic members are disposed on the body and/or the bearing body, and are configured to abut against a surface of an exclusion zone of the semiconductor substrate.

In the foregoing support apparatus, each of the elastic members may extend outward from the lower surface of the body, to form an elastic buffer height.

In the foregoing support apparatus, a plurality of cut-out slots may be connected between the upper surface and the lower surface of the body. Each of the elastic members may extend from a side wall of each of the cut-out slots to a direction of the lower surface of the body, to form an elastic buffer height.

In the foregoing support apparatus, a plurality of mounting holes may be connected between the upper surface and the lower surface of the body. Each of the elastic members may be inserted into each of the mounting holes.

In the foregoing support apparatus, the elastic member may include a head portion, a neck portion, and an abutting portion that are connected. The head portion may be buckled on the upper surface of the body. The neck portion may be engaged in the mounting hole. The abutting portion may protrude out of the lower surface of the body, to abut against a semiconductor substrate at a next level of the support apparatus.

In the foregoing support apparatus, the abutting portion may obliquely extend downward from the neck portion to expand outward, to form a multi-point abutting portion.

Based on this, the support apparatus of the present disclosure can improve versatility by disposing multiple bearing portions on the bearing body, to bear the semiconductor substrates with the different sizes. Therefore, the support apparatus of the present disclosure can effectively reduce the overall production costs, and greatly reduce a requirement for storage space. In addition, no subdivided management needs to be performed for each specification of support apparatus, so that management can be simplified, and management efficiency can be improved.

### BRIEF DESCRIPTION OF THE DRAWINGS

FIG. 1 is a diagram of a three-dimensional structure of a support apparatus according to an embodiment of the present disclosure.

FIG. 2A is a top view of a support apparatus according to an embodiment of the present disclosure, where a distribution range of a shared bearing portion of a bearing body is presented through grayscale coloring.

FIG. 2B is a top view of a support apparatus according to an embodiment of the present disclosure, where a distribution range of a first bearing portion of a bearing body is presented through grayscale coloring.

FIG. 2C is a top view of a support apparatus according to an embodiment of the present disclosure, where a distribution range of a second bearing portion of a bearing body is presented through grayscale coloring.

FIG. 3A is a top view of a support apparatus according to an embodiment of the present disclosure, where a condition in which a semiconductor substrate with a first size is borne is presented.

FIG. 3B is a top view of a support apparatus according to an embodiment of the present disclosure, where a condition in which a semiconductor substrate with a second size is borne is presented.

FIG. 4 is a partially enlarged view of a region A in FIG. 1, where a condition in which a semiconductor substrate is borne is presented.

FIG. 5 is a cross-sectional view along a line B-B in FIG. 2A.

FIG. 6 is a diagram of a partially enlarged view of a three-dimensional structure of a support apparatus according to another embodiment of the present disclosure.

FIG. 7 is a diagram of a partially enlarged view of a three-dimensional structure of a support apparatus according to still another embodiment of the present disclosure.

FIG. 8 is a top view of a structure in FIG. 7.

FIG. 9 is a cross-sectional view along a line C-C in FIG. 8.

### DETAILED DESCRIPTION OF THE INVENTION

To fully understand objectives, features, and effects of the present disclosure, the present disclosure is described in detail by using the following specific embodiments and with reference to the accompanying drawings. Descriptions are as follows.

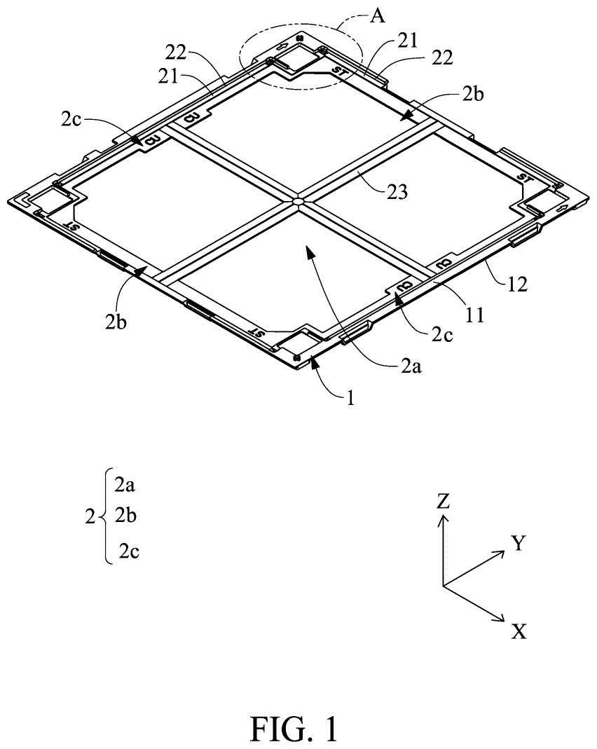

FIG. 1 to FIG. 3 show a preferred embodiment of a support apparatus of the present disclosure. The support apparatus of the present disclosure is disposed in a semiconductor container, and is configured to support a semiconductor substrate. The semiconductor container may be, for example, a loading device or a processing apparatus of a wafer carrier pod, a mask carrier pod, a carrier board carrier pod, or a carrier of another element during semiconductor processing. This is not limited in the present disclosure.

The support apparatus of this embodiment is applicable to a top opening semiconductor container, for example, a top opening carrier. The semiconductor container has an upper opening, and a bottom wall opposite to the upper opening is provided inside the semiconductor container. In addition, it may be defined that the upper opening and the bottom wall are opposite in a direction Z, which is an up-and-down direction. A length direction and a width direction of the semiconductor container are respectively a direction X and a direction Y. Certainly, the present disclosure is also applicable to a front opening semiconductor container, such as a front opening unified pod (FOUP). The type of the semiconductor container is not limited herein.

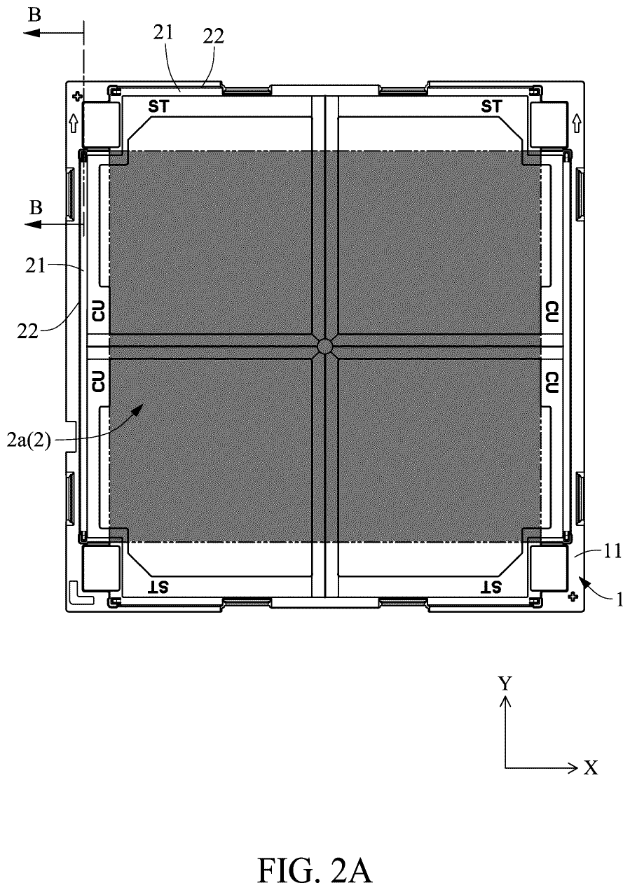

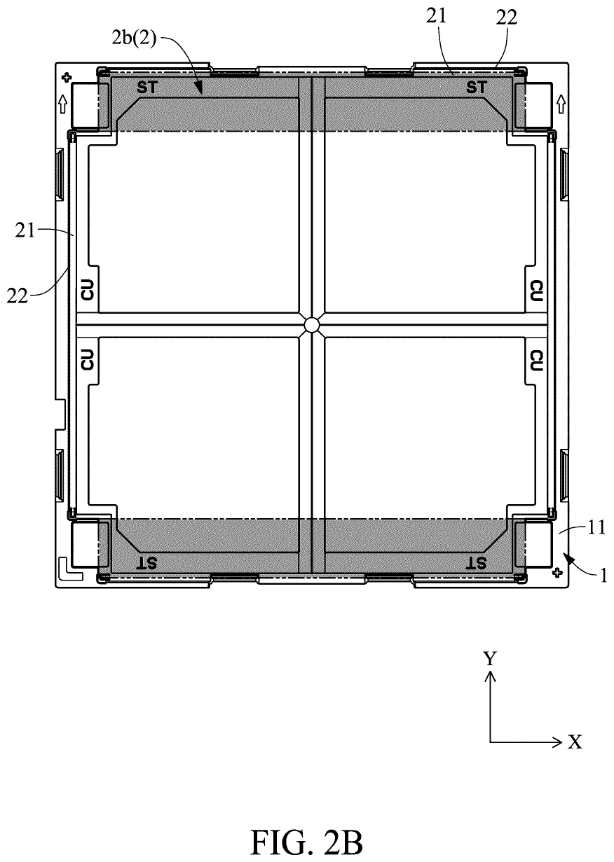

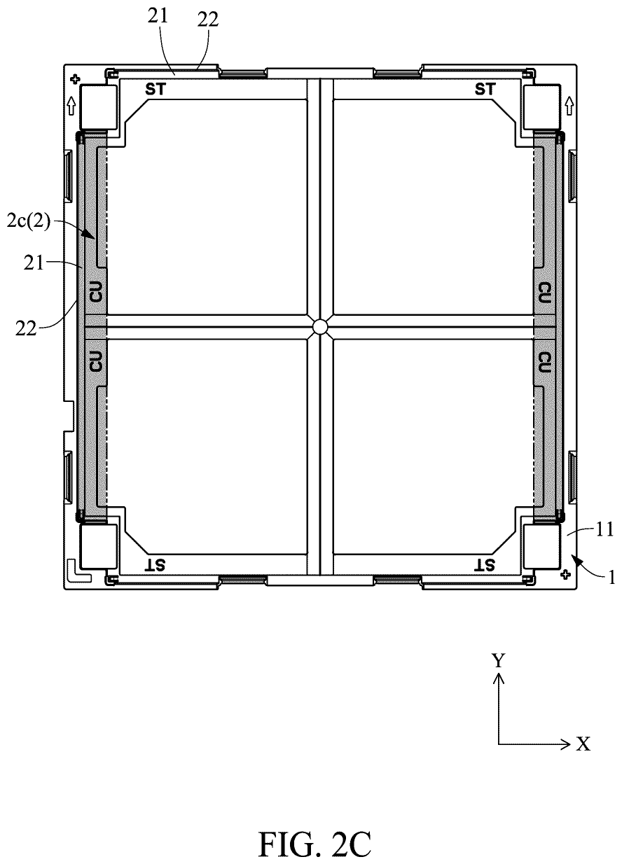

To be specific, the support apparatus of this embodiment includes a body 1 and a bearing body 2. The body 1 includes an upper surface 11 and a lower surface 12 that are opposite, and the upper surface 11 faces the opening of the semiconductor container. The bearing body 2 is disposed on the upper surface 11 of the body 1, and the bearing body 2 includes at least a shared bearing portion 2a, a first bearing portion 2b, and a second bearing portion 2c. FIG. 2A is a schematic diagram in which the shared bearing portion 2a is presented in grayscale coloring. FIG. 2B is a schematic diagram in which the first bearing portion 2b is presented in grayscale coloring. FIG. 2C is a schematic diagram in which the second bearing portion 2c is presented in grayscale coloring.

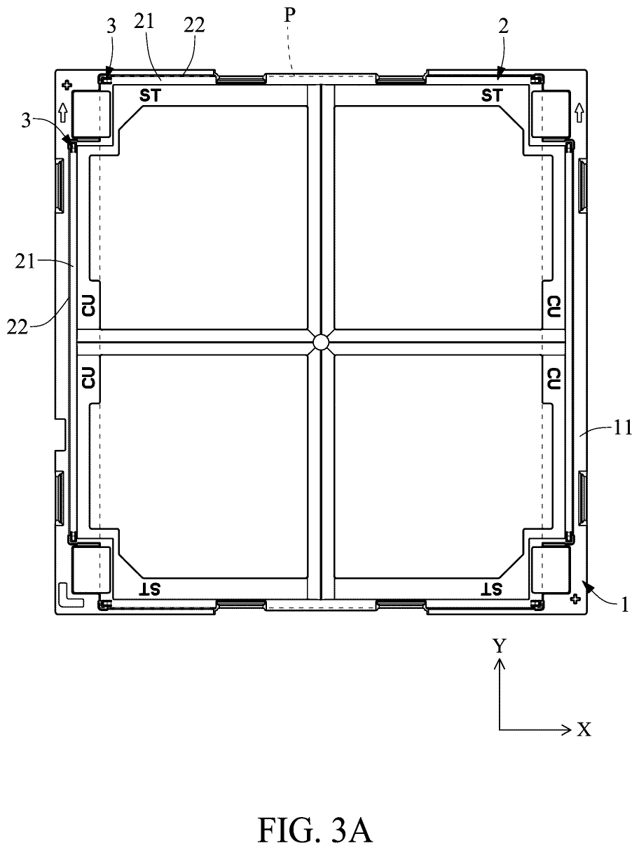

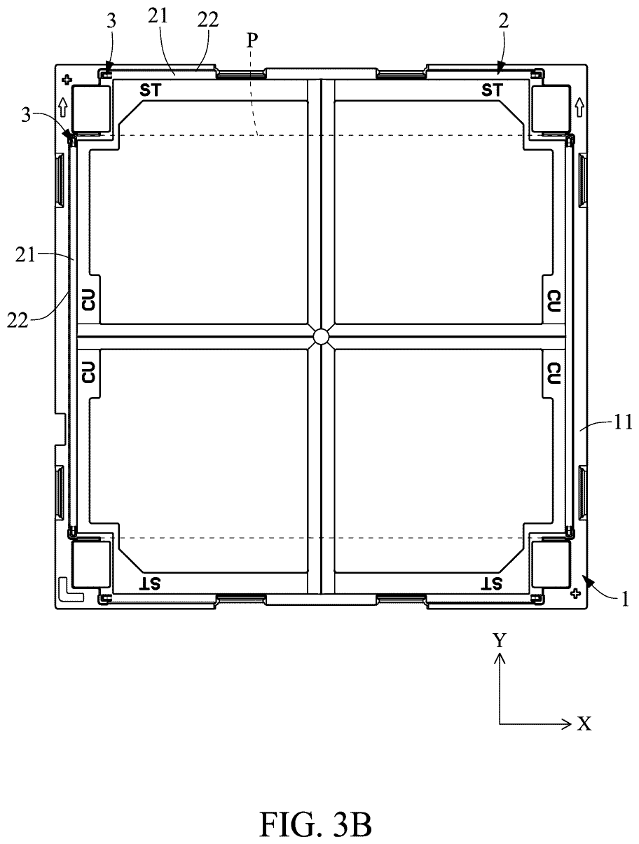

As shown in FIG. 2A, FIG. 2B, and FIG. 3A, the bearing body 2 is configured to dispose, based on a design pattern of a semiconductor substrate, the semiconductor substrate P on the shared bearing portion 2a and the first bearing portion 2b. Alternatively, as shown in FIG. 2A, FIG. 2C, and FIG. 3B, the bearing body 2 is configured to dispose, based on the design pattern of the semiconductor substrate, the semiconductor substrate P on the shared bearing portion 2a and the second bearing portion 2c. An area of the first bearing portion 2b is different from an area of the second bearing portion 2c, and the first bearing portion 2b and the second bearing portion 2c have some overlapping regions as the shared bearing portion 2a. Therefore, the shared bearing portion 2a plus the overlapping regions, the first bearing portion 2b, and the second bearing portion 2c are applicable to a design pattern different from an appearance, a size, a thickness, or any combination thereof of the semiconductor substrate P. The first bearing portion 2b and the second bearing portion 2c may respectively form recessed shapes of different sizes relative to the upper surface 11 of the body 1, to define limiting functions of semiconductor substrates P of different sizes, to bear the semiconductor substrates P of the different sizes.

Therefore, in comparison with a known tray dedicated to only a semiconductor substrate of a single size, the support apparatus of this embodiment has better versatility. To be specific, as shown in a range outlined by two-dot chain lines in FIG. 3A, the support apparatus of this embodiment may be configured to bear a single semiconductor substrate P of a first size. Alternatively, as shown in a range outlined by dashed lines in FIG. 3B, the support apparatus bears a single semiconductor substrate P of a second size. Therefore, the support apparatus of this embodiment can effectively reduce the overall production costs, and greatly reduce a requirement for storage space. In addition, no subdivided management needs to be performed for each specification of support apparatus, so that management can be simplified, and management efficiency can be improved.

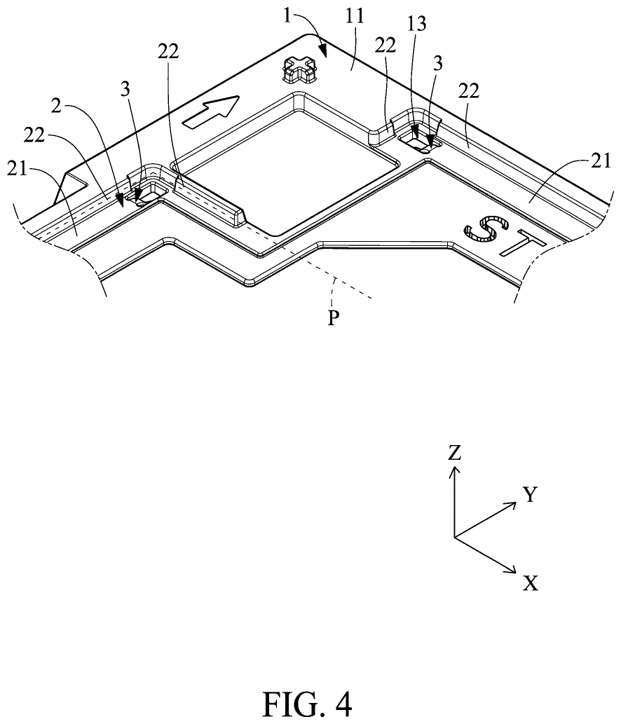

In addition, referring to FIG. 2B, FIG. 2C, and FIG. 4, in an embodiment of the present disclosure, the first bearing portion 2b and the second bearing portion 2c may be located on adjacent sides, and are configured to bear a design pattern of an appearance, a size, a thickness, or any combination thereof of a different semiconductor substrate.

In an embodiment of the present disclosure, upper surfaces of the first bearing portion 2b and the second bearing portion 2c are lower than the upper surface 11 of the body 1, to respectively define a recess at which the semiconductor substrate P is borne. In other words, the first bearing portion 2b and the second bearing portion 2c are both recessed at the upper surface 11, and respectively form at least a contact surface 21 and a plurality of side walls 22. The contact surface 21 is configured to abut against a lower surface of the semiconductor substrate P, and the side wall 22 is configured to abut against a peripheral edge of the semiconductor substrate P. In this way, two opposite outer edges of the semiconductor substrate P may be respectively aligned to two opposite sides of the body 1, and two adjacent side walls 22 jointly limit the semiconductor substrate P, so that it is difficult for the semiconductor substrate P to slide inside the first bearing portion 2b or the second bearing portion 2c.

In addition, referring to FIG. 1 to FIG. 3B, in an embodiment of the present disclosure, the bearing body 2 may include at least one bearing rib 23. The bearing rib 23 is connected to the shared bearing portion 2a and the first bearing portion 2b, to the shared bearing portion 2a and the second bearing portion 2c, to the shared bearing portion 2a, the first bearing portion 2b, and the second bearing portion 2c, or a combination thereof. In this way, the bearing rib 23 can be configured to improve structural stability of the body 1, and help support the semiconductor substrate P.

On the other hand, in an embodiment of the present disclosure, either of the first bearing portion 2b or the second bearing portion 2c may be divided into two parts, and the two parts are respectively symmetrically adjacent to two opposite sides of the body 1 relative to a middle position of the body 1 in the direction X or the direction Y. The first bearing portion 2b and the second bearing portion 2c may be disposed on adjacent sides of the body 1, or the contact surfaces 21 of the first bearing portion 2b and the second bearing portion 2c are further provided on the same side of the body 1 by a height difference, so that the semiconductor substrate P of the first size can be placed at a lower layer, or the semiconductor substrate P of the second size may be placed at an upper layer. The present disclosure is not limited thereto.

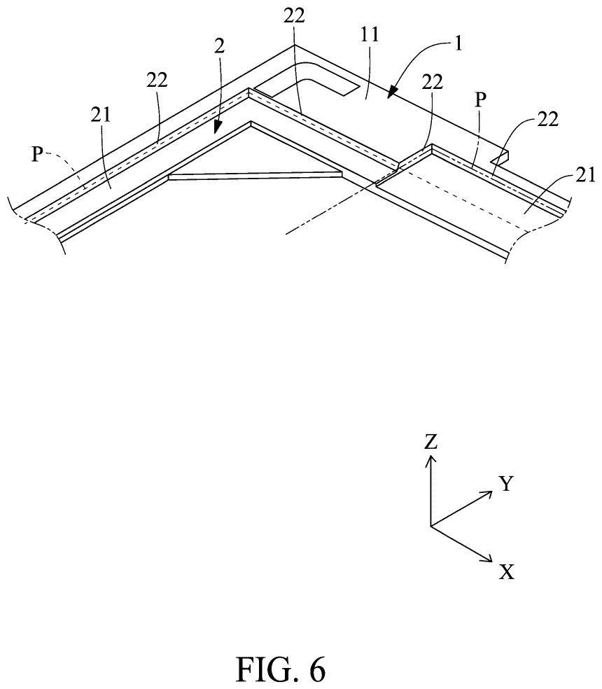

In the embodiment shown in FIG. 4, the contact surfaces 21 of the first bearing portion 2b and the second bearing portion 2c on the adjacent sides do not have a feature of the height difference, and the contact surfaces 21 of the first bearing portion 2b and the second bearing portion 2c may extend to be connected, or may not be connected. In another embodiment shown in FIG. 6, a pattern in which the contact surfaces 21 of the first bearing portion 2b and the second bearing portion 2c on the adjacent sides have the feature of the height difference is disclosed. Therefore, forms of the first bearing portion 2b and the second bearing portion 2c may change based on different use or design requirements, and are not limited by forms disclosed in the figures of the embodiments.

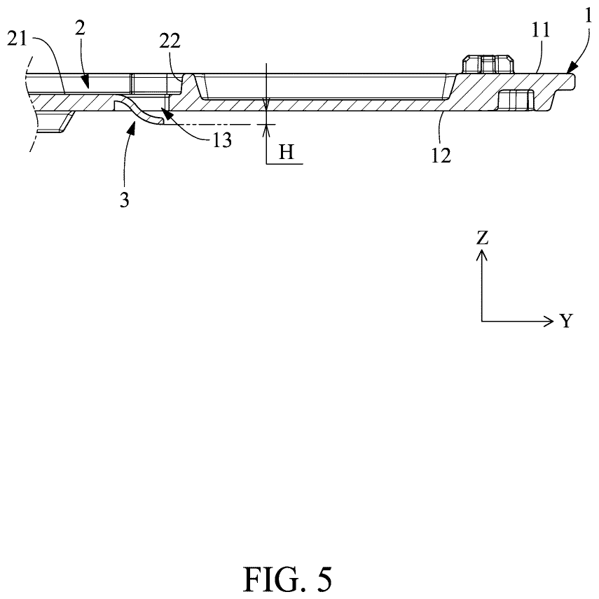

In addition, referring to FIG. 3A to FIG. 5, in an embodiment of the present disclosure, the support apparatus further includes a plurality of elastic members 3, and the plurality of elastic members 3 are disposed on the body 1 and/or the bearing body 2. When a plurality of support apparatuses are stacked, a plurality of elastic members 3 of a support apparatus at an upper layer can abut against the upper surface of a semiconductor substrate P borne by a support apparatus at an adjacent lower layer. An exclusion zone is usually formed close to an outer edge of the upper surface of the semiconductor substrate P, and the plurality of elastic members 3 preferably abut against the exclusion zone of the semiconductor substrate P.

Each of the elastic members 3 may extend outward from the lower surface 12 of the body 1, to form an elastic buffer height H. In other words, the elastic member 3 at least partially protrudes out of the lower surface 12 of the body 1. In addition, when no force is applied, the elastic buffer height H may be formed between a free end of the elastic member 3 and the lower surface 12 of the body 1 in the direction Z.

For example, the elastic member 3 may be in a form of an elastic piece. One end of the elastic member 3 may be connected to the lower surface 12 of the body 1, and obliquely extend. Alternatively, in an embodiment of the present disclosure, a plurality of cut-out slots 13 may be provided on the body 1. Each of the cut-out slots 13 communicates the upper surface 11 with the lower surface 12. One of the elastic members 3 is correspondingly disposed for each of the cut-out slots 13, and the elastic member 3 obliquely extends downward from a side wall of the corresponding cut-out slot 13, so that a free end of the elastic member 3 can penetrate out of the corresponding cut-out slot 13, to protrude out of the lower surface 12 of the body 1. Through a design of the cut-out slot 13, mechanical interference can be reduced, and an elastic buffer stroke can be increased.

Distribution positions of a part of the elastic members 3 are approximately aligned to the contact surface 21, so that a plurality of elastic members 3 of a support apparatus at an upper layer can abut against an upper surface of a semiconductor substrate P borne by a support apparatus at an adjacent lower layer. The quantity and distribution positions of the plurality of elastic members 3 are not limited in the present disclosure.

Based on this, free ends of a plurality of elastic members 3 of each support apparatus elastically abut against a semiconductor substrate P borne by a support apparatus at a next layer, so that a plurality of stacked support apparatuses can be abutted and supported, and the semiconductor substrate P is not damaged. Further, the plurality of elastic members 3 can limit up-and-down displacement of a semiconductor substrate at each layer, to avoid wafer slipping due to vibration during transportation, so that particles generated by friction can be effectively reduced, and a risk that the semiconductor substrate P is collided and damaged is reduced.

In addition, in an embodiment of the present disclosure, each of the elastic members 3 is preferably connected to the body 1 through integral forming. In this way, in this embodiment, the quantity of components that need to be assembled for the support apparatus can be reduced, and particles that may be generated between the components due to assembling or vibration can also be reduced.

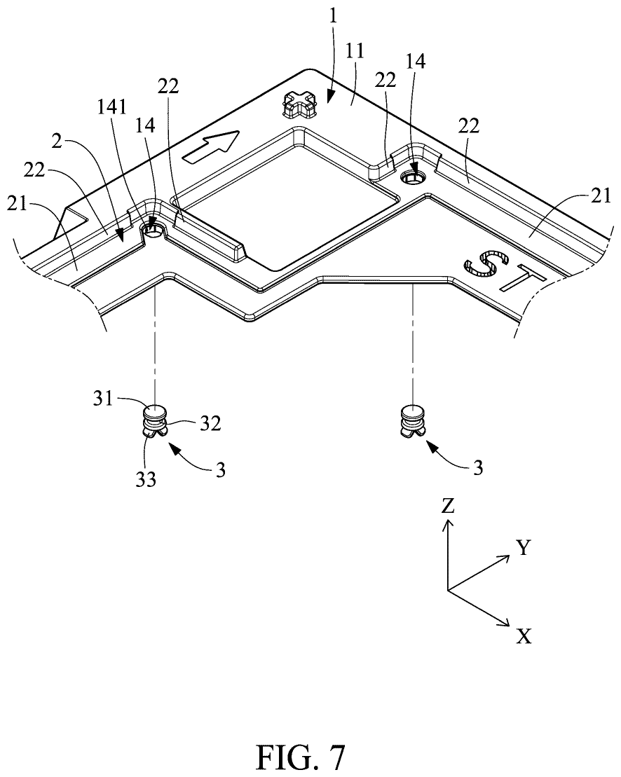

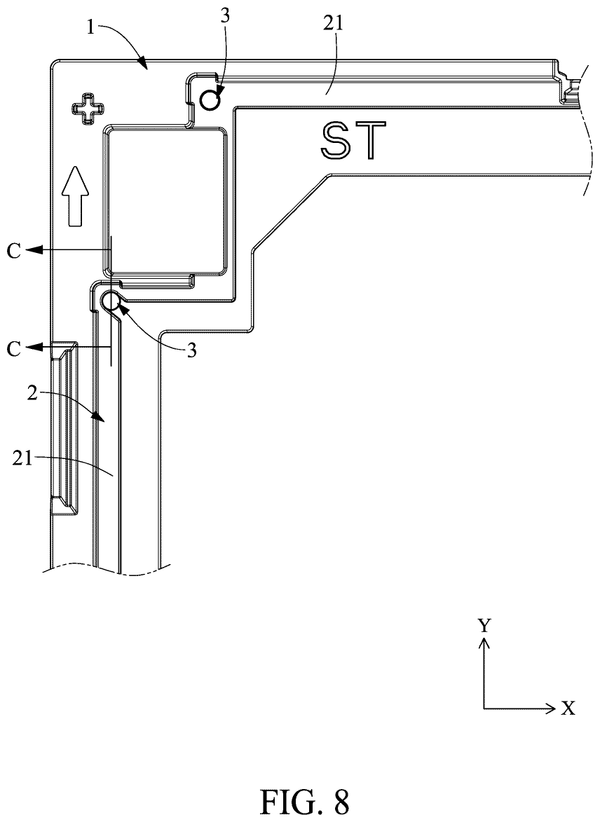

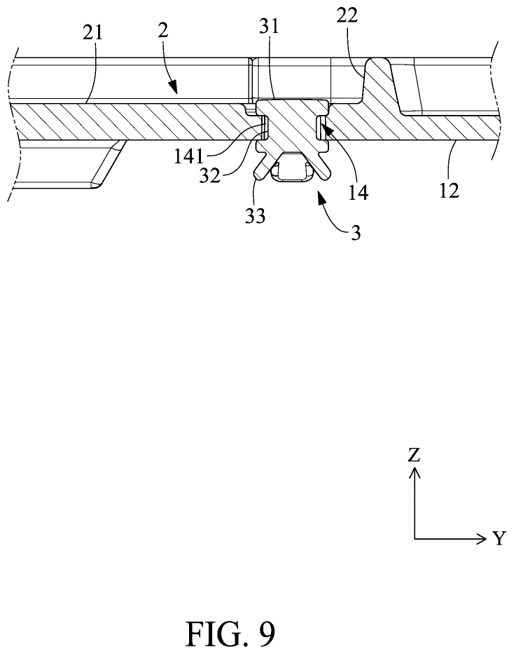

In another embodiment, each of the elastic members 3 may alternatively be disposed by assembling and combining the elastic member 3 with the body 1. This is not limited in the present disclosure. For example, in embodiments disclosed in FIG. 7 to FIG. 9, a plurality of mounting holes 14 may be provided on the body 1. Each of the mounting holes 14 communicates the upper surface 11 of the body 1 with the lower surface 12. Each of the mounting holes 14 may be inserted by one of the elastic members 3 for assembling and combination.

In an embodiment of the present disclosure, the elastic member 3 may include a head portion 31, a neck portion 32, and an abutting portion 33 that are connected. The head portion 31 is buckled on the upper surface 11 of the body 1. The neck portion 32 is engaged in the mounting hole 14. The abutting portion 33 protrudes out of the lower surface 12 of the body 1.

The head portion 31 may be an assembling body, or serve as a pressing portion during operation. A maximum width of the neck portion 32 in a cross-section X-Y is less than that of the mounting hole 14, and the head portion 31 is slightly larger than the mounting hole 14. The abutting portion 33 may obliquely extend downward from the neck portion 32 to expand outward, to form a multi-point abutting portion. In other words, the abutting portion 33 may include a plurality of sheet bodies obliquely extending downward and outward, so that the plurality of sheet bodies can jointly expand outward.

Based on this, the elastic member 3 may be assembled downward from the corresponding mounting hole 14, so that the head portion 31 is slightly deformed elastically to penetrate out of the mounting hole 14, and the head portion 31 is engaged outside the mounting hole 14. The neck portion 32 abuts against an inner wall of the mounting hole 14. When the abutting portion 33 penetrates through the mounting hole 14 to the outside of the lower surface 12 of the body 1, the abutting portion 33 is elastically expanded, so that a diameter width is greater than an inner diameter width of the mounting hole 14, so that the abutting portion 33 is limited on the body 1 and/or the bearing body 2, that is, the abutting portion 33 can be configured to elastically abut against the semiconductor substrate P on the support apparatus at the next layer, and the up-and-down displacement of the semiconductor substrate at each layer can also be limited. In addition, in this embodiment, quick disassembling and assembling of the elastic member 3 is facilitated. A suitable elastic member 3 is assembled on the body 1 and/or the bearing body 2 of the support apparatus based on semiconductor substrates P of different sizes, so that the elastic member 3 can stably and fixedly abut against a semiconductor substrate P at an adjacent layer.

In addition, to enable each of the elastic members 3 to be more stably and fixedly combined with the corresponding mounting hole 14, at least one inner convex portion 141 may further be disposed on the inner wall of the mounting hole 14, so that a cross-section X-Y of the mounting hole 14 is in a locally protruding form, and the neck portion 32 correspondingly extends into the inner convex portion 141, to help support and position the head portion 31.

The elastic member 3 is an integral sheet body or an assembled elastic member, and is only an optimal implementation pattern. The design structure is not limited by the present disclosure, and shall belong to the protection scope of the present disclosure provided that the elastic member is disposed on the body 1 and/or the bearing body 2.

The present disclosure is disclosed above by using preferred embodiments. However, a person skilled in the art should understand that the embodiments are only used to describe the present disclosure, and should not be understood as a limitation to the scope of the present disclosure. It should be noted that any equivalent modification or replacement of the embodiments should be included in the scope of the present disclosure. Therefore, the protection scope of the present disclosure should be defined by the appended claims, and the scope of the appended claims should be given the broadest reasonable interpretation, to include all modifications, similar arrangement, and procedures therein.

What is claimed is:

1. A support apparatus, disposed in a semiconductor container, wherein the support apparatus comprises:
a body, comprising an upper surface and a lower surface that are opposite; and
a bearing body, disposed on the upper surface of the body, wherein the bearing body comprises a shared bearing portion, a first bearing portion, and a second bearing portion, wherein
the bearing body is configured to dispose, based on a design pattern of a semiconductor substrate, the semiconductor substrate on the shared bearing portion and the first bearing portion, or the shared bearing portion and the second bearing portion.

2. The support apparatus according to claim 1, wherein the first bearing portion and the second bearing portion are located on adjacent sides, and are configured to bear a design pattern of an appearance, a size, a thickness, or any combination thereof of a different semiconductor substrate.

3. The support apparatus according to claim 1, wherein upper surfaces of the first bearing portion and the second bearing portion are lower than the upper surface of the body, to define a recess at which the semiconductor substrate is borne.

4. The support apparatus according to claim 1, wherein the bearing body comprises at least one bearing rib, and the bearing rib is connected to the shared bearing portion and the first bearing portion, to the shared bearing portion and the second bearing portion, to the shared bearing portion, the first bearing portion, and the second bearing portion, or a combination thereof.

5. The support apparatus according to claim 1, wherein a plurality of elastic members are disposed on the body and/or the bearing body, and are configured to abut against a surface of an exclusion zone of the semiconductor substrate.

6. The support apparatus according to claim 5, wherein each of the elastic members extends outward from the lower surface of the body, to form an elastic buffer height.

7. The support apparatus according to claim 5, wherein a plurality of cut-out slots are connected between the upper surface and the lower surface of the body, and each of the elastic members extends from a side wall of each of the cut-out slots to a direction of the lower surface of the body, to form an elastic buffer height.

8. The support apparatus according to claim 5, wherein a plurality of mounting holes are connected between the upper surface and the lower surface of the body, and each of the elastic members is inserted into each of the mounting holes.

9. The support apparatus according to claim 8, wherein the elastic member comprises a head portion, a neck portion, and an abutting portion that are connected, the head portion is buckled on the upper surface of the body, the neck portion is engaged in the mounting hole, and the abutting portion protrudes out of the lower surface of the body, to abut against a semiconductor substrate at a next level of the support apparatus.

10. The support apparatus according to claim 9, wherein the abutting portion obliquely extends downward from the neck portion to expand outward, to form a multi-point abutting portion.
